(19) United States
(12) Patent Application Publication
(10) Pub. No.: US 2014/0159180 A1
(43) Pub. Date: Jun. 12, 2014

(54) SEMICONDUCTOR RESISTOR STRUCTURE AND SEMICONDUCTOR PHOTOMULTIPLIER DEVICE

(71) Applicant: Agency for Science, Technology and Research, Singapore (SE)

(72) Inventors: Fei Sun, Singapore (SG); Ning Duan, Singapore (SG); Patrick Guo-Qiang Lo, Singapore (SG)

(21) Appl. No.: 14/099,782

(22) Filed: Dec. 6, 2013

(30) Foreign Application Priority Data
Dec. 6, 2012 (SG) 201208976.9

(51) Int. Cl. H01L 29/8605; H01L 31/10

(52) U.S. Cl. CPC H01L 29/8605; H01L 31/10
USPC 257/431; 257/536

(57) ABSTRACT

According to embodiments of the present invention, a semiconductor resistor structure is provided. The semiconductor resistor structure includes a substrate, a first region of a first conductivity type in the substrate, a second region of the first conductivity type in the substrate, the first region and the second region arranged one over the other, and an intermediate region of a second conductivity type in between the first region and the second region, wherein at least one gap is defined through the intermediate region and overlapping with the first region and the second region. According to further embodiments of the present invention, a semiconductor photomultiplier device is also provided.

### CROSS-REFERENCE TO RELATED APPLICATION

This application claims the benefit of priority of Singapore patent application No. 201208976-9, filed 6 Dec. 2012, the content of it being hereby incorporated by reference in its entirety for all purposes.

### TECHNICAL FIELD

Various embodiments relate to a semiconductor resistor structure and a semiconductor photomultiplier device.

### BACKGROUND

In recent years, silicon photomultipliers (SiPMs) have been developed as a possible alternative to photomultiplier tubes (PMTs), due to their many advantages, such as compactness, low bias voltage operation, magnetic field insensitivity and fast timing response. SiPMs can also take advantage of the highly developed silicon (Si) process technologies and the modern fabrication facilities for batch-processing in the semiconductor industry, which guarantees robustness and low fabrication costs of the devices. Nowadays, the performances of SiPMs are fast approaching those of conventional PMTs. SiPMs have found widespread applications in high-energy physics, fluorescence and luminescence decay measurements, single-molecule detection, laser ranging, nuclear medical imaging like Positron Emission Tomography (PET), radiation detection for homeland security systems, and so on.

FIG. 1 shows a schematic configuration of a silicon photomultiplier (SiPM) device 100. A SiPM device 100 is a two-terminal device (e.g. having a positive terminal 102a and a negative terminal 102b) made of large numbers of identical cells, as represented by 103 for two cells, connected to each other in parallel. Each cell 103 is formed by an avalanche photo diode (APD) 104 and a quenching resistor 105, as shown schematically in FIG. 1.

In the SiPM operating mechanism, when light is launched to the SiPM 100, photons at different locations will be collected by corresponding APDs 104 and be absorbed by the material of the APDs 104, which is Si, which results in generation of electron/hole pairs. In order to achieve high detection sensitivity, the APDs 104 are reversely biased under a voltage higher than the breakdown voltage, which is the voltage beyond which avalanche process occurs. Thus, the generated free earners (electrons and holes) will then be accelerated by the high electric field in the device 100 to acquire speeds high enough to trigger avalanche processes. Accordingly, the incident photons can be detected by the diodes 104 in the form of amplified avalanche currents.

In spite of the fact that the APDs 104 work in a Geiger mode, the SiPM 100 is still expected to be an analog device to quantitatively measure the intensity of the incident light. For that, the resistor 105 in series with the APD 104 is necessary to control the current and the power consumption of the diode 104. The resistor 105 can also be used to quench the avalanche current and turn off the fired diode 104, so that it can get ready for detection of another incident photon. The output of the SiPM 100 will be the analogue sum of the current from each cell 103, corresponding to the intensity of the incident light. The photon detection efficiency (PDE) of a SiPM may be given by the product of three parameters: the quantum efficiency (QE), the avalanche triggering probability (P_{trigger}), and the fill factor (FF). The PDE may be determined using Equation 1 below,

PDE=QE×FF×P_{trigger} (Equation 1).

The configuration of silicon APDs is basically a p-n junction, with some possible supplementary structures to improve the device performances. Polysilicon (poly-Si) strips are normally adopted to serve as quenching resistors. FIG. 2A shows a schematic top view of part of a conventional silicon photomultiplier (SiPM) device 200. The SiPM device 200 is shown as having 12 SiPM cells, where each SiPM cell is as represented within the dotted line box 202. The SiPM cell 202 includes a diode 201 including a detection window 204, which represents a region through which light or photons may pass into the SiPM cell 202, and an active region 206, which represents a region or area where light that passes through the detection window 204 may be absorbed. The SiPM cell 202 further includes a poly-Si resistor 208, and one or more metal wires 210. The poly-Si resistor 208 acts as a quenching resistor for the diode 201. The metal wire(s) 210 is (are) employed to connect the diode 201 and the poly-Si resistor 208, and for electrical connections among the SiPM cells 202 of the SiPM device 200. The SiPM device 200 further includes one or more common or shared metal wires, e.g. 212, which is/are shared by a group of six SiPM cells 202, as indicated by 214. While not clearly shown in FIG. 2A, the active region 206 may span and overlap with the area of the detection window 204 and the metal wire(s) 210, as is shown in FIG. 21B.

FIG. 2B shows a schematic cross-sectional view of a conventional silicon photomultiplier (SiPM) cell 202 of the silicon photomultiplier (SiPM) device 200 of FIG. 2A. The SiPM cell 202 has a SACM (Separation of Absorption, Charge, Multiplication) structure. The SiPM cell 202 includes a diode (Diode 1) 201a, which includes a detection window 204, and an active region 206 that is highly doped (p+ region), formed in a silicon (Si) substrate 240. The diode 201a further includes a lightly doped (p− region) region 242 formed in the substrate 240. The SiPM cell 202 further includes a quenching resistor 208 electrically coupled to the active region 206 is a metal wire 210. The SiPM cell 202 further includes a passivation or insulating layer 211.

Also shown in FIG. 2B are diodes corresponding to respective adjacent SiPM cells. For example, a second diode (Diode 2) 201b, with its corresponding p+ region (active region) 252, p− region 254 and metal wire 256, is shown to the right side of the diode 201a, while a third diode (Diode 3) 201c, with its corresponding p+ active region 262, p− region 264, quenching resistor 266, metal wire 268 and passivation layer 270, is shown to the left side of the diode 201a.

The SiPM device 200 includes a common electrode 274 formed in the substrate 240, opposite to the active p+ regions 206, 252, 262. The common electrode 274 is highly doped, of a conductivity type opposite to that of the p+ regions 206, 252, 262, i.e. the common electrode 274 is an n+ region. Using the diode 201a as an example, a diode is therefore formed between the p+ region 206 and the n+ common electrode 274. The common electrode 274 is shared by the diode 201a, the second diode 201b and the third diode 201c. The SiPM device 200 further includes a metal wire 276 adjacent to the common electrode 274. The remaining portion of the substrate 240 may be intrinsic, or undoped.

As can be seen from FIGS. 2A and 2B, the individual diodes (e.g. 201, 201a, 201b, 201c) are serially connected to neighboring poly-Si resistors (e.g. 208, 266) by metal wires (e.g. 210, 268), and the metal bus line (e.g. 212) then connects all the cells 202 in parallel, forming one terminal of the SiPM device 200. The other terminal of the device 200, being the common electrode 274, is connected to the substrate 240 and shared by all the cells 202, serving as the other electrode in the diodes 201, 201a, 201b, 201c.

For the SiPM device 200, as shown in FIGS. 2A and 2B, only part of the device surface is adopted to collect incident photons. The areas outside the detection windows 204 are assigned to accommodate the metal wires 210, 268, poly-Si resistors 208, 266, and so oil. Therefore, photons launched in these “dead regions” (areas outside the detection window 204) are quite unlikely to be detected. The fill Factor (FF) for a SiPM is defined as the area ratio between the detection window (e.g. 204) and the surface of the whole device, where the detection efficiency of a SiPM device increases with its fill factor. Hence, the SiPM device 200 has a low fill factor due to the presence of the “dead regions”, resulting in a low detection efficiency.

Further, in order to achieve efficient quenching of the avalanche current, the resistance of the poly-Si resistors 208, 266, is expected to be in the order of 10⁵Ω or even larger. The control of such a high resistance will bring much technological challenges in the related fabrication processes such as poly-Si deposition, doping, patterning, annealing and contacting. In addition, as shown in FIG. 2B, the bumpy surface caused by the poly-Si resistors 208, 266 will bring extra difficulties in the subsequent processes, such as deposition and patterning of the metal wires 210, 268.

FIG. 3 shows a schematic cross-sectional view of a silicon photomultiplier (SiPM) cell 302 of a part of a silicon photomultiplier (SiPM) device 300 of prior art. The SiPM cell 302 has a SACM (Separation of Absorption, Charge=Multiplication) structure. The SiPM cell 302 includes a diode (Diode 1) 301a, which includes a detection window 304, and an active region 306, which is highly doped (p+ region), formed in a silicon (Si) substrate 340. The diode 301a further includes a lightly doped (p− region) region 342 formed in the substrate 340. The SiPM cell 302 further includes a highly doped contact region (p+ region) 380 formed laterally from the active region 306, and spaced apart from the active region 306 by a separation region 312, which defines a bulk quenching resistor between the active region 366 and the contact region 380. The contact region 380 is electrically coupled to the metal wire 310, which is shared by adjacent SiPM cells of the SiPM device 300. The SiPM cell 302 further includes a passivation or insulating layer 311.

Also shown in FIG. 3 are diodes corresponding to respective SiPM cells adjacent to the SiPM cell 302. For example, a second diode (Diode 2) 301b, with its corresponding p+ region (active region) 352, p− region 354 and passivation layer 311, is shown to the right side of the diode 301a, while a third diode (Diode 3) 301c, with its corresponding p+ active region 362, p− region 364, and passivation layer 370, is shown to the left side of the diode 301a.

The SiPM device 300 includes a common electrode 374 formed in the substrate 340, opposite to the active p+ regions 306, 352, 362. The common electrode 374 is highly doped, of a conductivity type opposite to that of the p+ regions 306, 352, 362, i.e. the common electrode 374 is an n+ region. Using diode 301a as an example, a diode is therefore formed between the p+ region 306 and the n+ common electrode 374. The common electrode 374 is shared by the diode 301a, the second diode 301b and the third diode 301c. The SiPM device 300 further includes a metal wire 376 adjacent the common electrode 374. The remaining portion of the substrate 340 may be intrinsic or undoped.

The SiPM device 300 may provide a high fill factor and increased photon detection efficiency. As can be seen in FIG. 3, the poly-Si resistors employed in the SiPM device 200 (FIGS. 2A and 2B) are replaced by a lateral bulk-Si resistor 312 surrounding the active region 306 of the SiPM cell 302. Since the resistor 312 is connected with the diode 301a inherently, no metal wire connection is needed in the active region 306. Thus, a high fill factor can be achieved. Furthermore, because of the separation of the active region 306 and the anode contact region 380, the doping profiles in these two regions can be optimized separately, which can help to achieve a higher quantum efficiency. However, the resistance of the lateral quenching resistor 312 is greatly influenced by the fabrication fluctuations such as the doping profiles and the alignment issues. Furthermore, although the dead region on the device surface has been reduced greatly, for example as compared to the SiPM device 200, there are still some areas being occupied by the metal wires 310 and the passivation layers 311, 370.

SiPMs have been investigated and developed for many years, and many ideas and technologies have been adopted to increase the fill factors of SiPMs. However, there remains challenges associated with conventional SiPMs, for example in terms of the dark current/dark count rate and/or the photon detection efficiency (PDE). For example, conventional SiPMs have high dark current, high crosstalk, and low fill factor (FF). Also, during operation, some conventional SiPMs have a long recovery time, for example as a consequence of the long distance between electrodes.

Furthermore, relatively complicated fabrication processes may be required to fabricate conventional SiPM devices, consequently resulting in a decrease in yield and an increase in the fabrication cost. For some conventional SiPM devices, advanced wafer bonding or epitaxial technologies will be needed to realize the thick epitaxial layers. There are also issues of poor reproducibility of the conventional SiPM devices. There are also issues related to small fabrication tolerances.

### SUMMARY

According to an embodiment, a semiconductor resistor structure is provided. The semiconductor resistor structure may include a substrate, a first region of a first conductivity type in the substrate, a second region of the first conductivity type in the substrate, the first region and the second region arranged one over the other, and an intermediate region of a second conductivity type in between the first region and the second region, wherein at least one gap is defined through the intermediate region and overlapping with the first region and the second region.

According to an embodiment, a semiconductor photomultiplier device is provided. The semiconductor photomultiplier device may include a substrate having a front side and a back side, at least one cell including a first region of a first conductivity type adjacent to the back side, a second region of the first conductivity type in the substrate over the first region, an intermediate region of a second conductivity type in between the first region and the second region, wherein at least one gap is defined through the intermediate region and overlapping with the first region and the second region, and an active region of the second conductivity type adjacent to the front side.

### BRIEF DESCRIPTION OF THE DRAWINGS

In the drawings, like reference characters generally refer to like parts throughout the different views. The drawings are not necessarily to scale, emphasis instead generally in being placed upon illustrating the principles of the invention. In the following description, various embodiments of the invention are described with reference to the following drawings, in which:

FIG. 1 shows a schematic configuration of a silicon photomultiplier (SiPM) device.

FIG. 2A shows a schematic top view of part of a conventional silicon photomultiplier (SiPM) device.

FIG. 2B shows a schematic cross-sectional view of a conventional silicon photomultiplier (SiPM) cell of the silicon photomultiplier (SiPM) device of FIG. 2A.

FIG. 3 shows a schematic cross-sectional view of a silicon photomultiplier (SiPM) cell of a part of a silicon photomultiplier (SiPM) device of prior art.

FIG. 4A shows a schematic cross-sectional view of a semiconductor resistor structure, according to various embodiments.

FIG. 4B shows a schematic cross-sectional view of a semiconductor photomultiplier device, according to various embodiments.

FIG. 5 shows a schematic cross-sectional view of a semiconductor resistor structure, according to various embodiments.

FIG. 6A shows a schematic cross-sectional view of a silicon photomultiplier (SiPM) cell of a part of a silicon photomultiplier (SiPM) device having a SACM (Separation of Absorption, Charge, Multiplication) structure, according to various embodiments.

FIG. 6B shows a schematic cross-sectional view of a silicon photomultiplier (SiPM) cell of a part of a silicon photomultiplier (SiPM) device having a reach-through structure, according to various embodiments.

FIGS. 6C and 6D show respective schematic cross-sectional views of terminals for a silicon photomultiplier (SiPM) device of various embodiments.

FIGS. 7A and 7B show plots of simulation results of the doping profile of a vertical bulk-Si resistor, and the current density when an overvoltage is applied on the substrate of the vertical bulk-Si resistor, respectively, according to various embodiments.

FIG. 8A shows a plot of I-V (current-voltage) curves of vertical bulk-Si resistors for different radii of the active region, according to various embodiments.

FIG. 8B shows a plot of resistance variation for vertical bulk-Si resistors under a 5 V bias for different thicknesses of the resistor layer and diameters of the hole, according to various embodiments.

FIGS. 9A, 9B and 9C show plots of simulation results of the doping profile of a silicon photomultiplier (SiPM) device, the electric field distribution and the current density distribution of the SiPM device operating above the breakdown voltage, respectively, according to various embodiments.

FIG. 10A shows a plot of I-V (current-voltage) curves of a silicon photomultiplier (SiPM) cell of various embodiments and a conventional SiPM cell.

FIG. 10B shows a plot of simulation results for the blue light responses of a silicon photomultiplier (SiPM) cell of various embodiments and a conventional SiPM cell.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the devices are analogously valid for the other device.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element includes a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may relate to a semiconductor photomultiplier device. For example, various embodiments may provide a silicon (Si) photomultiplier (SiPM) device, for medical imaging and biophotonics, e.g. Si-CMOS (complementary metal-oxide-semiconductor) imaging.

Various embodiments may provide a semiconductor photomultiplier device, e.g. a silicon photomultiplier (SiPM) device. Vertical bulk-Si quenching resistors may be introduced into the structure of the SiPM device, replacing poly-Si resistors. The omission of poly-Si simplifies the fabrication process and effectively increases the fill factor of the device. Thus, a higher yield and a higher photon detection efficiency may be expected.

Various embodiments may provide a design of a silicon photomultiplier (SiPM) device integrated with vertical bulk-Si quenching resistors. The cross-section of the vertical resistor may be reduced by inserting current blocking layers and forming back-to-back diodes in the resistor structure. As a result of the high resistivity of intrinsic Si, the dimension of the resistor may be made very small, while maintaining the necessary high resistance, for example in the order of 10⁵Ω. As the vertical resistor may be achieved or fabricated by Si epitaxial growth and ion implantation, the resistor may be connected with the diode inherently. Thus, no metal wire connection is needed in the active region of the SiPM device. Furthermore, the omission of poly-Si related processing not only simplifies the fabrication process, but also results in a flat and unstructured detection surface. A high fill factor (FF) may be achieved accordingly. The effective fill factor may be improved from 37% in conventional designs to about 94.5% in the SiPM structures of various embodiments. Compared to conventional SiPM, the SiPM device of various embodiments may have advantages of higher detection efficiency, more flexible device design and simpler fabrication processes.

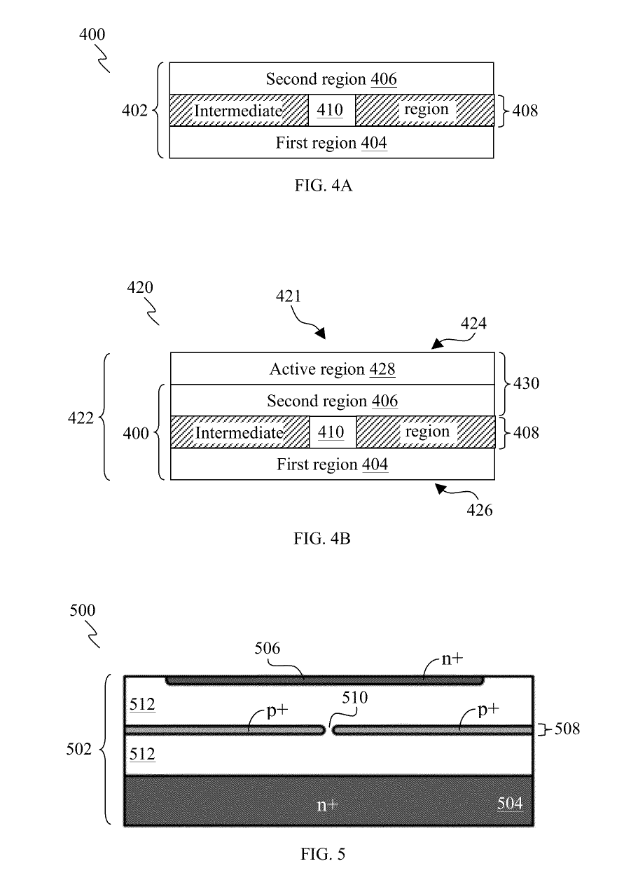

FIG. 4A shows a schematic cross-sectional view of a semiconductor resistor structure 400, according to various embodiments. The semiconductor resistor structure 400 includes a substrate 402, a first region 404 of a first conductivity type in the substrate 402, a second region 406 of the first conductivity type in the substrate 402, the first region 404 and the second region 406 arranged one over the other, and an intermediate region 408 of a second conductivity type in between the first region 404 and the second region 406, wherein at least one gap 410 is defined through the intermediate region 408 and overlapping with the first region 404 and the second region 406.

In other words, the semiconductor resistor structure 400 may include a substrate 402 including a first region 404 and a second region 406 formed one above the other. The first region 404 and the second region 406 may be of the same conductivity type. The semiconductor resistor structure 400 may further include an intermediate region 408 formed in the substrate 402, sandwiched in between the first region 404 and the second region 406, and of a conductivity type that is opposite to those of the first region 404 and the second region 406. At least one gap (e.g. an opening or a hole) 410 may be formed through the intermediate region 408 at a position that may at least substantially overlap with the first region 404 and the second region 406. The at least one gap 410 may be an undoped region or an intrinsic region defined in the intermediate region 408.

In various embodiments, the first region 404 and the second region 406 may be provided towards opposite sides of the substrate 402. For example, the first region 404 may be provided adjacent to a back side of the substrate 402, while the second region 406 may be provided adjacent to a front side of the substrate 402.

In various embodiments, the first region 404 may be a lower region and the second region 406 may be an upper region. This may mean that the second region 406 may be arranged vertically over the first region 404.

In various embodiments, the at least one zap 410 may be arranged to overlap centrally with at least one of the first region 404 or the second region 406, e.g. at a position at least substantially corresponding to the respective centre points of the first region 404 and/or the second region 406.

In various embodiments, the first region 404 and the intermediate region 408 may define a diode, while the second region 406 and the intermediate region 408 may define another diode. As each of the first region 404 and the second region 406 is of an opposite conductivity type compared to the intermediate region 408, the first region 404, the second region 406 and the intermediate region 408 may define back-to-back diodes.

In various embodiments, in response to a bias or voltage applied to the first region 404 and the second region 406, a current may flow between the first region 404 and the second region 406 through the at least one gap 410 but the current may be blocked by the remaining portions of the intermediate region 408 without any gaps. This may mean that the intermediate region 408 may act as a current blocking region or layer, and that the current may not flow through the intermediate region 408, except through the at least one gap 410 that is defined through the intermediate region 408. Therefore, the at least one gap 410 may define a resistor.

As the at least one gap 410 is defined in the substrate 402, the resistor is a bulk resistor. Accordingly, the semiconductor resistor structure 400 may be a bulk semiconductor resistor structure. In the context of various embodiments, the semiconductor resistor structure may achieve a resistance in a range of between about 10³Ω and about 10⁷Ω, for example between about 10³Ω and about 10⁵Ω, between about 10⁵Ω and about 10⁷Ω, or between about 10⁴Ω and about 10⁶Ω, e.g. a resistance of about 10⁵Ω.

In various embodiments, as the current flows between the first region 404 and the second region 406 through the at least one gap 410, a vertical bulk resistor may be defined in the semiconductor resistor structure 400.

In the context of various embodiments, the semiconductor resistor structure 400 may include silicon (Si), meaning that the substrate 402 may include Si (e.g. a Si substrate or a silicon-on-insulator substrate). This also means that the semiconductor resistor structure 400 may be a silicon resistor structure, where a vertical bulk Si resistor may be defined. However, it should be appreciated that other semiconductor materials may be used for achieving the semiconductor resistor structure 400, although there may be challenges in terms of the dark current and the wafer cost.

In the context of various embodiments, the first region 404, the second region 406 and the intermediate region 408 may be formed in one or more epitaxial layers (e.g. Si epitaxial layer(s)). The total thickness of the epitaxial layer(s) may vary from about 100 nanometers (nm) to 100 microns (μm) or so, for example between about 100 nm and about 100 μm, e.g. between about 100 nm and about 50 μm, between about 100 nm and about 10 μm, between about 100 nm and about 1 μm, between about 1 μm and about 100 μm, between about 20 μm and about 100 μm, or between about 50 μm and about 100 μm.

In the context of various embodiments, the substrate 402 may include a support carrier and one or more epitaxial layers formed on the support carrier. The first region 404, the second region 406 and the intermediate region 408 may be formed in the epitaxial layer(s). Alternatively, the first region 404 may be the support carrier itself, while the second region 406 and the intermediate region 408 may be formed in the epitaxial layers(s).

In the context of various embodiments, the at least one gap 410 may have a dimension (e.g. diameter or width) varying from about 100 nanometers to 100 microns or so, for example between about 100 nm and about 100 μm, e.g. between about 100 nm and about 50 μm, between about 100 nm and about 10 μm, between about 100 nm and about 1 μm, between about 1 μm and about 100 μm, between about 20 μm and about 100 μm, or between about 50 μm and about 100 μm. The resistance achieved by the semiconductor resistor structure 400 may be varied by changing the dimension of the at least one gap 410.

In various embodiments, a plurality of gaps 410 may be defined through the intermediate region 408, where the plurality of gaps 410 may at least substantially overlap with the first region 404 and the second region 406. In this way, the resistance achieved by the semiconductor resistor structure 400 may be varied by changing the number of the plurality of gaps 410.

In various embodiments, the intermediate region 408 may be spaced apart from at least one of the first region 404 or the second region 406. The remaining portions of the substrate 402 may be intrinsic or undoped portions.

In various embodiments, the intermediate region 408 may be arranged equidistant from each of the first region 404 and the second region 406. However, it should be appreciated that the intermediate region 408 may be arranged at different respective distances from each of the first region 404 and the second region 406, i.e. not equidistant.

In the context of various embodiments, a distance between the first region 404 and the second region 406 may vary from about 100 nanometers to 100 microns or so, for example between about 100 nm and about 100 μm, e.g. between about 100 nm and about 50 μm, between about 100 nm and about 10 μm, between about 100 nm and about 1 μm, between about 1 μm and about 100 μm, between about 20 μm and about 100 μm, or between about 50 μm and about 100 μm. The resistance achieved by the semiconductor resistor structure 400 may be varied by changing the distance between the first region 404 and the second region 406.

In various embodiments, the first region 404 may be thicker than the second region 406.

In the context of various embodiments, the first region 404 may be doped with dopants of the first conductivity type at a concentration of between about 10¹⁸/cm³ and about 10²¹/cm³, for example between about 10¹⁸/cm³ and about 10²⁰/cm³, between about 10¹⁸/cm³ and about 10¹⁹/cm³, or between about 10¹⁹/cm³ and about 10²¹/cm³.

In the context of various embodiments, the second region 406 may be doped with dopants of the first conductivity at a concentration of between about 10¹⁸/cm³ and about 10²¹/cm³, for example between about 10¹⁸/cm³ and about 10²⁰/cm³, between about 10¹⁸/cm³ and about 10¹⁹/cm³, or between about 10¹⁹/cm³ and about 10²¹/cm³.

In the context of various embodiments, the intermediate region 408 may be doped with dopants of the second conductivity type at a concentration of between about 10¹⁵/cm³ and about 10²¹/cm³, for example between about 10¹⁵/cm³ and about 10¹⁸/cm³, between about 10¹⁸/cm³ and about 10²¹/cm³, or between about 10¹⁶/cm³ and about 10²⁰/cm³.

In the context of various embodiments, the first conductivity type may be an n-type conductivity type, and the second conductivity type may be a p-type conductivity type. Alternatively, the first conductivity type may be a p-type conductivity type, and the second conductivity type may be an n-type conductivity type.

FIG. 4B shows a schematic cross-sectional view of a semiconductor photomultiplier device 420, according to various embodiments. The semiconductor photomultiplier device 420 includes a substrate 422 having a front side 424 and a back side 426, at least one cell 421 including a first region 404 of a first conductivity type adjacent to the back side 426, a second region 406 of the first conductivity type in the substrate 422 over the first region 404, an intermediate region 408 of a second conductivity type in between the first region 404 and the second region 406, wherein at least one gap 410 is defined through the intermediate region 408 and overlapping with the first region 404 and the second region 406, and an active region 428 of the second conductivity type adjacent to the front side 424.

In other words, the semiconductor photomultiplier device 420 may include a substrate 422, a first region 404, which may be formed in the substrate 422, and a second region 406 formed above the first region 404. The first region 404 and the second region 406 may be of the same conductivity type. The semiconductor photomultiplier device 420 may further include an intermediate region 408 formed in the substrate 422, sandwiched in between the first region 404 and the second region 406, where the intermediate region 408 may be of a conductivity type that is opposite to those of the first region 404 and the second region 436. At least one gap (e.g. an opening or a hole) 410 may be formed through the intermediate region 408 at a position that may at least substantially overlap with the first region 404 and the second region 406. The at least one gap 410 may be an undoped region or an intrinsic region defined in the intermediate region 408. The semiconductor photomultiplier device 420 may further include an active region 428, which may be formed in the substrate 422, of a same conductivity type as that of the intermediate region 408. The active region 428 and the first region 404 may be provided towards opposite sides of the substrate 422. In various embodiments, the active region 428 may also act as a contact region for the at least one cell 421.

In various embodiments, the second region 406 may at least substantially overlap with the active region 428.

In various embodiments, the at least one gap 410 may at least substantially overlap with the active region 428. The at yeast one gap 410 may be arranged to overlap centrally with the active region 428, e.g. at a position at least substantially corresponding to the centre point of the active region 428.

The first region 404, the second region 406, the intermediate region 408 and the at least one gap 410 may define a semiconductor resistor stricture 400 as described in the context of FIG. 4A. The second region 406 and the active region 428 may define a diode 430. Accordingly, the cell 421 of the semiconductor photomultiplier device 420 may include a diode 430 and a resistor structure 400, which may be serially connected to each other. The diode 430 may be an avalanche photodiode (APD). The diode 430 may be operated in a Geiger mode.

In various embodiments, the second region 406 may be shared by the diode 430 and the resistor structure 400, e.g. acting as a lower electrode or contact region for the diode 430 and as an upper electrode or contact region for the resistor structure 400. Therefore, the diode 430 and the resistor structure 400, acting as a quenching resistor, may be serially connected to each other inherently in the at least one cell 421. As a result, no metal wires are needed in the cell 421.

In various embodiments, the resistor structure 400 may define a vertical bulk resistor. Therefore, a semiconductor photomultiplier device 420 with at least one vertical bulk quenching resistor may be provided.

In various embodiments, the active region 428 may correspond to a detection window where photons may be incident onto and collected by the at least one cell 421.

In the context of various embodiments the active region 428 may be doped with dopants of the second conductivity type at a concentration of between about 10¹⁸/cm³ and about 10²¹/cm³, for example between about 10¹⁸/cm³ and about 10²⁰/cm³, between about 10¹⁸/cm³ and about 10¹⁹/cm³, or between about 10¹⁹/cm³ and about 10²¹/cm³.

In various embodiments, a plurality of gaps 410 may be defined through the intermediate region 408, the plurality of gaps 410 overlapping with the first region 404 and the second region 406. In this way, the resistance achieved by the semiconductor resistor structure 400 may be varied by changing the number of the plurality of gaps 410.

In various embodiments, the intermediate region 408 may be spaced apart from at least one of the first region 404 or the second region 406. The remaining portions of the substrate 422 may be intrinsic or undoped portions.

In various embodiments, the intermediate region 408 may be arranged equidistant from each of the first region 404 and the second region 406. However, it should be appreciated that the intermediate region 408 may be arranged at different respective distances from each of the first region 404 and the second region 406, i.e. not equidistant.

In various embodiments, the at least one cell 421 may further include another intermediate region of the second conductivity type between the active region 428 and the second region 406. The other intermediate region may act as a charge layer. The other intermediate region may be spaced apart from at least one of the active region 428 or the second region 406. The other intermediate region may be arranged equidistant from each of the active region 428 and the second region 406. However, it should be appreciated that the other intermediate region may be arranged at different respective distances from each of the active region 428 and the second region 406, i.e. not equidistant. The other intermediate region may include dopants of the second conductivity type at a concentration equal to or lower than a concentration of dopants of the second conductivity type in the active region 428. In the context of various embodiments, the other intermediate region may be doped with dopants of the second conductivity type at a concentration of between about 10¹⁴/cm³ and about 10¹⁸/cm³, for example between about 10¹⁴/cm³ and about 10¹⁶/cm³, between about 10¹⁶/cm³ and about 10¹⁸/cm³, or between about 10¹⁵/cm³ and about 10¹⁷/cm³.

In various embodiments the at least one cell 421 may further include another intermediate region of the first conductivity type between the active region 428 and the second region 406. The other intermediate region may at least substantially contact the active region 428. The other intermediate region may extend into the substrate 422 towards the second region 406. The other intermediate region may include dopants of the first conductivity type at a concentration equal to or lower than a concentration of dopants of the first conductivity type in the second region 406. In the context of various embodiments, the other intermediate region may be doped with dopants of the first conductivity type at a concentration of between about 10¹⁴/cm³ and about 10¹⁸/cm³, for example between about 10¹⁴/cm³ and about 10¹⁶/cm³, between about 10¹⁶/cm³ and about 10¹⁸/cm³, or between about 10¹⁵/cm³ and about 10¹⁷/cm³.

In various embodiments, the semiconductor photomultiplier device 420 may include a plurality of cells 421 including the first region 404 and the active region 428, wherein each cell 421 may include a second region 406 of the first conductivity type in the substrate 422 over the first region 404, and an intermediate region 408 of the second conductivity type in between the first region 404 and the second region 406, wherein at least one gap 410 is defined through the intermediate region 408, the at least one gap 410 overlapping with the first region 404 and the second region 406. A respective portion of the active region 428 corresponding to a respective cell 421 may define a respective detection window for the respective cell 421. Respective second regions 406 of respective cells 421 may be separated from each other.

The active region 428 may be a common electrode or contact region shared by the plurality of cells 421, e.g. a continuous active region 428. The first region 404 may be a common electrode or contact region shared by the plurality of cells 421, i.e. a continuous first region 404. This may mean that the plurality of cells 421 may be connected in parallel. Therefore, the active region 428 and the first region 404 may provide two terminals for the semiconductor photomultiplier device 420.

In various embodiments, each cell 421 of the plurality of cells 421 may further include another intermediate region of the first conductivity type or the second conductivity type between the active region 428 and the second region 406. Respective other intermediate regions of respective cells 421 may be separated from each other.

The semiconductor photomultiplier device 420 may further include at least one guard region of the first conductivity type, wherein a guard region of the at least one guard region may be arranged in between respective second regions 406 of adjacent cells 421 of the plurality of cells 421. The guard region may be in contact with the respective second regions 406 of adjacent cells 421. A respective guard region may at least substantially surround a respective cell 421. In various embodiments, the at least one guard region may include dopants of the first conductivity type at a concentration lower than a concentration of dopants of the first conductivity type in the second region 406. The at least one guard region may be doped with dopants of the first conductivity type at a concentration of between about 10¹³/cm³ and about 10¹⁷/cm³, for example between about 10¹³/cm³ and about 10¹⁵/cm³, between about 10¹⁵/cm³ and about 10¹⁷/cm³, or between about 10¹⁴/cm³ and about 10¹⁶/cm³.

In various embodiments, the semiconductor photomultiplier device 420 may further include an electrical interconnection (e.g. a contact pad, e.g. a metal pad) electrically coupled to the active region 428. The semiconductor photomultiplier device 420 may further include another electrical interconnection (e.g. a contact pad, e.g. a metal pad) electrically coupled to the first region 404. The other electrical interconnection may include a conductive via formed through the substrate 422. Each of the electrical interconnection and the other electrical interconnection may be positioned outside the array area or detection area of the semiconductor photomultiplier device 420. This may mean that each of the electrical interconnection and the other electrical interconnection may be arranged outside of an area or region corresponding to the at least one cell 421.

In the context of various embodiments, an area of the front side 424 of the substrate 422 to which the active region 428 is adjacent may be free of electrical interconnections, e.g. metal wires.

In the context of various embodiments, a surface of the substrate 422 on the front side 424 may be free of resistors or integrated resistors.

In the context of various embodiments, the semiconductor photomultiplier device 420 may be free of polysilicon resistors.

In the context of various embodiments, the semiconductor photomultiplier device 420 may include silicon (i), meaning that the substrate 422 may include Si (e.g. a Si substrate or a silicon-on-insulator substrate). This also means that the semiconductor photomultiplier device 420 may be a silicon photomultiplier (SiPM) device, with a vertical bulk-Si resistor structure. However, it should be appreciated that other semiconductor materials may be used for achieving the semiconductor photomultiplier device 420, although there may be challenges in terms of the dark current and the wafer cost.

In the context of various embodiments, the first region 404, the second region 406, the intermediate region 408 and the active region 428 may be formed in one or more epitaxial layers (e.g. Si epitaxial layer(s)). The total thickness of the epitaxial layer(s) may vary from about 100 nanometers to 100 microns or so, for example between about 100 nm and about 100 μm, e.g. between about 100 nm and about 50 μm, between about 100 nm and about 10 μm, between about 100 nm and about 1 μm, between about 1 μm and about 100 μm, between about 20 μm and about 100 μm, or between about 50 μm and about 100 μm.

In the context of various embodiments, the substrate 422 may include a support carrier and one or more epitaxial layers formed on the support carrier. The first region 404, the second region 406, the intermediate region 408 and the active region 428 may be formed in the epitaxial layer(s). Alternatively, the first region 404 may be the support carrier itself, while the second region 406, the intermediate region 408 and the active region 428 may be formed in the epitaxial layer(s).

In the context of various embodiments if the semiconductor resistor structure 400 and the semiconductor photomultiplier device 420, the different regions (e.g. first region 404, second region 406, intermediate region 408, active region 428, etc.) may be formed using ion implantation processes.

Various embodiments may provide a silicon (Si) photomultiplier (SiPM) structure with vertical bulk-Si quenching resistors to replace the poly-Si resistors employed in conventional devices. Therefore, various embodiments may provide a SiPM structure without the need for poly-Si related processes. Further, elimination of metal wires on the surface of the SiPM cells may be achieved in the SiPM device of various embodiments. Various embodiments may also provide a SiPM structure with increased fill factor (FF).

FIG. 5 shows a schematic cross-sectional view of a semiconductor resistor structure 500, according to various embodiments. As a non-limiting example, the semiconductor resistor structure 500 may realise a vertical bulk-Si quenching resistor.

The semiconductor resistor structure 500 will now be described using silicon (Si), as a non-limiting example, as the material for the semiconductor resistor structure 500. The Si resistor structure 500 may be realized by Si epitaxial growth and ion implantation processes. The resistor structure 500 may include a Si substrate 502, including a doped region (e.g. a first region) 504, which may be a highly doped n+ region. The n+ region 504 may be formed towards a lower region of the Si substrate 502. The substrate 502 may further include a doped region (e.g. a second region) 506, which may be a highly doped n+ region. The n+ region 506 may be formed towards an upper region of the Si substrate 502. Therefore, the two n+ regions 504, 506 may be of die same conductivity type, e.g. comprising dopants of the same conductivity type. The n+ region 504 may be thicker than the n+ region 506. The n+ region 506 may at least substantially overlap with at least a portion of the n+ region 504.

The substrate 502 may further include a doped region (e.g. an intermediate region) 508, which may be a highly doped p+ region. The p+ region 508 may be formed in between the n+ regions 504, 506, and of a conductivity type that is opposite to the conductivity type of the n+ regions 504, 506. Therefore, the n+ region 504 and the p+ region 508 may form a diode (e.g. a pn diode), and the n+ region 506 and the p+ region 508 may form another diode (e.g. a pn diode). In this way, back-to-back diodes may be defined in the Si resistor structure 500.

As illustrated in FIG. 5, the p+ region 308 may at least substantially overlap with the n+ regions 504, 506. The p+ region 508 may be formed spaced apart from the n+ regions 504, 506. Further, the p+ region 508 may be formed equidistant from the n+ regions 504, 506. Therefore, there may be intrinsic or undoped regions 512 in between the n+ region 506 and the p+ region 508 and between the n+ region 504 and the p+ region 508. In further embodiments, it should be appreciated that the p+ region 508 may not be formed equidistant from each of the n+ regions 504, 506.

A gap (e.g. an opening or a hole) 510 may be defined through the p+ region 508, where the gap 510 may be formed between the n+ regions 504, 506 and at least substantially overlapping with the n+ regions 504, 506. The gap 510 may be an intrinsic or undoped region in the substrate 502. It should be appreciated that one or more gaps 510 may be formed through the p+ region 508, at least substantially overlapping with the n+ regions 504, 506.

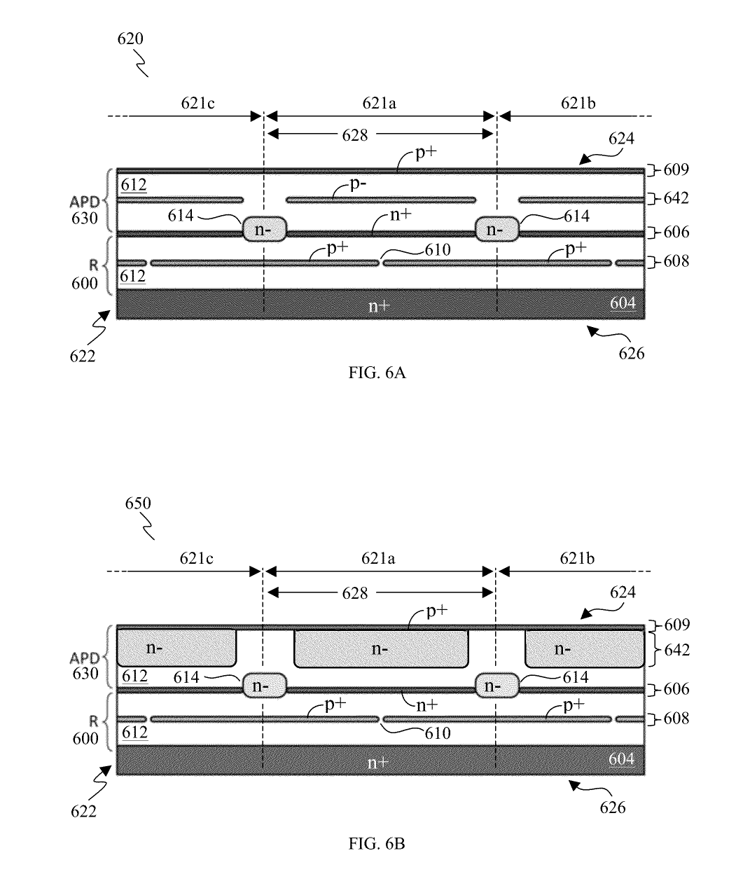

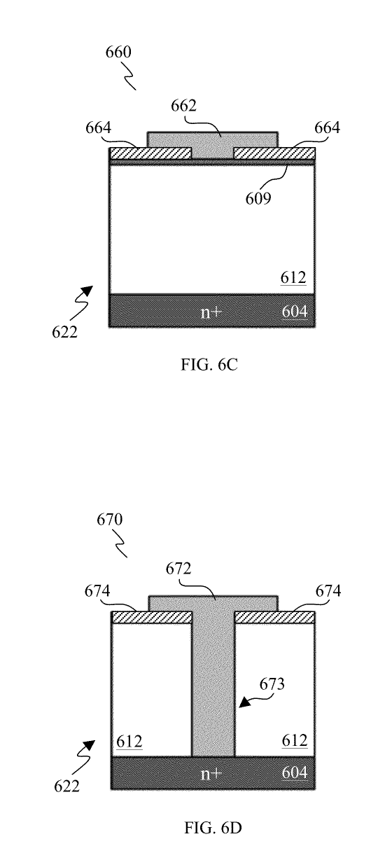

As will be described later with reference to FIGS. 6A and 6B, the n+ region 506 may overlap with an active region in a diode of a semiconductor photomultiplier device incorporating the semiconductor resistor structure 500. For example an area of the n+ region 506 may be identical to that of the active region in the diode. The p+ region 508 may cover all the device area except leaving small gaps (e.g. holes) 510 at positions corresponding to the vicinity of the center of the active region.

As a result of the back-to-back diode structure defined by the n+ regions 504, 506 and the p+ region 508 of different doping types, when a bias is applied between the n+ regions 504, 506, the resulting current may be blocked in or by the p+ region 508. As a consequence, the current may only flow through the small gap 510 defined through the p+ region 508. Thus, a bulk-Si resistor with a very small cross-section may be achieved. Accordingly, a thin epitaxial Si layer, e.g. the substrate 502 where the n+ region 504, the p+ region 508 and the n+ region 506 may be formed, may be sufficient to achieve a resistance in the order of approximately 10⁵Ω. As the current flows between the n+ regions 504, 506 through the gap 510, a vertical resistor may be defined.

While FIG. 5 shows an n-p-n structure for the vertical bulk resistor 500, it should be appreciated that a p-n-p structure may instead be adopted. For example, the structure employed for the resistor structure 500 may depend on any device to be electrically coupled to the resistor structure 500, e.g. depending on the design of an avalanche photo diode (APD) structure that may be coupled to the resistor structure 500 for a photomultiplier device.

Non-limiting examples of silicon photomultiplier (SiPM) cells, formed by incorporation of vertical bulk-Si resistors (e.g. the resistor structures 500) with diodes (e.g. avalanche photo diodes (APDs)), may be as shown in FIGS. 6A and 6B. The SiPM structure of various embodiments may be referred to as an “SiPM with vertical resistor”, or “VR-SiPM” for short.

FIG. 6A shows a schematic cross-sectional view of a silicon photomultiplier (SiPM) cell 621a of a part of a silicon photomultiplier (SiPM) device 620 having a SACM (Separation of Absorption, Charge, Multiplication) structure, according to various embodiments. For illustration purposes, the SiPM device 620 is shown with the SiPM cell 621a and parts of adjacent cells 621b, 621c. It should be appreciated that the SiPM device 620 may have any number of SiPM cells. The SiPM device 620 may be realized by Si epitaxial growth and ion implantation processes, and may be formed in a silicon (Si) substrate 522.

Using the cell 621a as a non-limiting example, the cell 621a includes a diode (e.g. an avalanche photo diode (APD)) 630 and a resistor structure (R) 600 electrically coupled in series. The resistor structure 600 includes a doped region (e.g. a first region) 604, which may be a highly doped n+ region adjacent to a back side 626 of the substrate 622, another doped region (e.g. a second region) 606, which may be a highly doped n+ region, and a further doped region (e.g. an intermediate region) 608, which may be a highly doped p+ region, in between the n+ regions 604, 606. The n+ region 606 may not be formed across the entire width of the cell 621a. A gap (e.g. an opening or a hole) 610 may be defined through the p+ region 608, at least substantially overlapping with the n+ regions 604, 606. It should be appreciated that a plurality of gaps 610 may be formed through the p+ region 608. As described, the resistor structure 600 may have an n-p-n structure. As a result, a back-to-back diode structure defined by the n+ regions 604, 606 and the p+ region 608 may be formed in the resistor structure 600. The resistor structure 600 may define a vertical resistor where, in response to a bias applied to the resistor structure 600, a current may flow between the n+ regions 604, 606 through the gap 610 while being blocked by the p+ region 608. This may mean that, during operation, the back-to-back pit Junctions or diodes defined by the n+ regions 604, 606 and the p+ region 608 may be reversed biased, where the resulting current may be blocked by the reversely biased pn junctions and may only flow through the small hole defined by the gap 610. Therefore, the SiPM device 620 may be a VR-SiPM device, incorporating a vertical resistor.

In various embodiments, the n+ region 604 may serve as a lower electrode for the resistor structure 600, while the n+ region 606 may serve as an upper electrode for the resistor structure 600.

As illustrated in FIG. 6A, the n+ region 606 may at least substantially overlap with at least a portion of the n+ region 604. The p+ region 608 may at least substantially overlap with the n+ regions 664, 606. The p+ region 668 may be formed spaced apart in from the n+ regions 604, 606. Further, the p+ region 608 may be formed equidistant from the n+ regions 604, 606. Therefore, there may be intrinsic or undoped regions 612 in between the n+ region 606 and the p+ region 608 and between the n+ region 604 and the p+ region 608. In further embodiments, it should be appreciated that the p+ region 608 may not be formed equidistant from each of the n+ regions 604, 606.

It should be appreciated that the n+ region 604, the n+ region 606 and the p+ region 608 may be as described in the context of the n+ region 504, the n+ region 506 and the p+ region 508, respectively, of the resistor stricture 500 (FIG. 5). Further, it should be appreciated that the resistor structure 600 may instead have a p-n-p structure.

The diode 630 includes the n+ region 606, which may be shared with the resistor structure 600, and a doped region 669, which may be a highly doped p+ region, from which an active region 623 may be defined adjacent to a front side 624 of the substrate 622. The active region 628 also defines a detection window for the cell 621a through which photons may be received by the diode 630, and therefore also received by the cell 621a. The diode 630 may include a further doped region 642, which may be a lightly doped p− region, formed within or embedded in the substrate 622 as an intermediate region between the n+ region 606 and the active region 628. The p− region 642 may not be formed across the entire width of the cell 621a.

The p− region 642 may at least substantially overlap with the n+ region 606 and the active region 628. The p− region 642 may be arranged beneath the active region 628 and spaced apart from the active region 628. The p− region 642 may be spaced apart from the n+ region 606. Further, the p− region 642 may be formed equidistant from the n+ region 606 and the active region 628. There may be intrinsic or undoped regions 612 in between the n+ region 606 and the p− region 642 and between the active region 628 and the p− region 642. In further embodiments, it should be appreciated that the p− region 642 may not be formed equidistant from each of the n+ region 606 and the active region 623.

In various embodiments, the n+ region 606 may serve as a lower electrode for the diode 630, while the active region 623 and therefore the p+ region 609 may serve as an upper electrode for the diode 630.

In various embodiments, the lower electrodes (n+ region 606) of the diodes 630 are shared with the upper electrodes (n+ region 606) of the resistors 600. Thus, the diodes 630 and the vertical bulk-Si quenching resistors 600 may be serially connected to each other inherently, with no metal wires needed in the SiPM cells 621a, 621b, 621c.

As shown in FIG. 6A, the VR-SiPM device 620 may further include two doped regions 614 having the same doping type as that for the shared electrodes (n+ region 606). For example, the doped regions 614 may be lightly doped n− region. Each n− region 614 may be arranged in between respective n+ regions 606 of adjacent cells, e.g. between cells 621a, 621c. While not clearly shown, the n− regions 614 may form a continuous region at least substantially surrounding the cell 621a.

In the diodes 630, these n− regions 614 may be used as guard rings surrounding each cell 621a, 621b, 621c, to improve the uniformity of electric fields and reduce the early breakdown at the edges of the active regions 628. Further, these n− regions 614 may be adopted to block any current leakage between the two p+ regions 608, 609. Therefore, these n− regions 614 may serve as blocking regions between the resistor 600 and the upper electrode (p+ region 609) of the diode 630. For the purpose of serving, any one or more of the above-mentioned functions, the n− regions 614 may be formed in contact with the shared electrodes (n+ region 606) and cover all the blank areas between adjacent cells 621a, 621b, 621c.

In various embodiments, the p+ region or layer 609 may be formed across the cells 621a, 6216, 621c, and may be employed as a common contact region shared by the cells 621a, 621b, 621c. It should be appreciated that the p+ region 609 may act as a common contact region or anode for all cells in the VR-SiPM device 620. Further, the n+ region 604 may be formed across the cells 621a, 621b, 621c, and may be employed as a common contact region shared by the cells 621a, 621b, 621c. It should be appreciated that the n+ region 604 may at as a common contact region or cathode for all cells in the VR-SiPM device 620. Therefore, the VR-SiPM device 620 may be a two-terminal device.

While the diodes 630 illustrated in FIG. 6A have a SACM (separate absorption, charge, and multiplication) structure, where the doped regions 642, serving as charge layers, may be either p− (as shown in FIG. 6A) or n− type, it should be appreciated that the VR-SiPM structure of various embodiments is not so limited. Any other diode configurations, such as the reach-through structure illustrated in FIG. 6B, may also be incorporated with the vertical bulk-Si resistor to realize the VR-SiPM devices of various embodiments. Besides, the doping types of different regions in the VR-SiPM structure is not limited to the ones shown in FIG. 6A. VR-SiPM devices may also be designed quite flexibly for different applications.

FIG. 6B shows a schematic cross-sectional view of a silicon photomultiplier (SiPM) cell 621a of a part of a silicon photomultiplier (SiPM) device 650 having a reach-through structure, according to various embodiments. For illustration purposes, the SiPM device 650 is shown with the SiPM cell 621a and parts of adjacent cells 621b, 621c. Similarly, the SiPM device 650 may be a VR-SiPM device.

The reach-through structure may be similar to that of the SACM stricture of FIG. 6A except that the intermediate region 642 of the reach-through structure may be of a conductivity type opposite to that of the active region 628. For example, the intermediate region 642 may be a lightly doped n− region. The n− region 642 may be formed adjacent and in contact with the active region 628. The n− region 642 may extend into the substrate 622 towards the n+ region 606.

The two terminals of the SiPM devices 620, 650 may be placed outside the SiPM array area by connecting respective contact pads (e.g. metal pads) with the heavily doped p+ region 609 and the heavily doped n+ substrate 604, as shown in FIGS. 6C and 6D. FIG. 6C shows a cross-sectional view of a terminal 660 formed by electrically coupling a contact pad 662 to the p+ region 609, with a passivation layer (e.g. silicon oxide, SiO₂) 664 therebetween, except for a contact point between the contact pad 662 and the p+ region 609. FIG. 6E) shows a cross-sectional view of a terminal 670 formed by electrically coupling a contact pad 672 to the n+ region 604, through a conductive via 673 formed through the intrinsic region 612 of the substrate 622. A passivation layer (e.g. silicon oxide, SiO₂) 674 may be formed between the contact pad 672 and the intrinsic region 612, except where the contact pad 672 is formed into the conductive via 673.

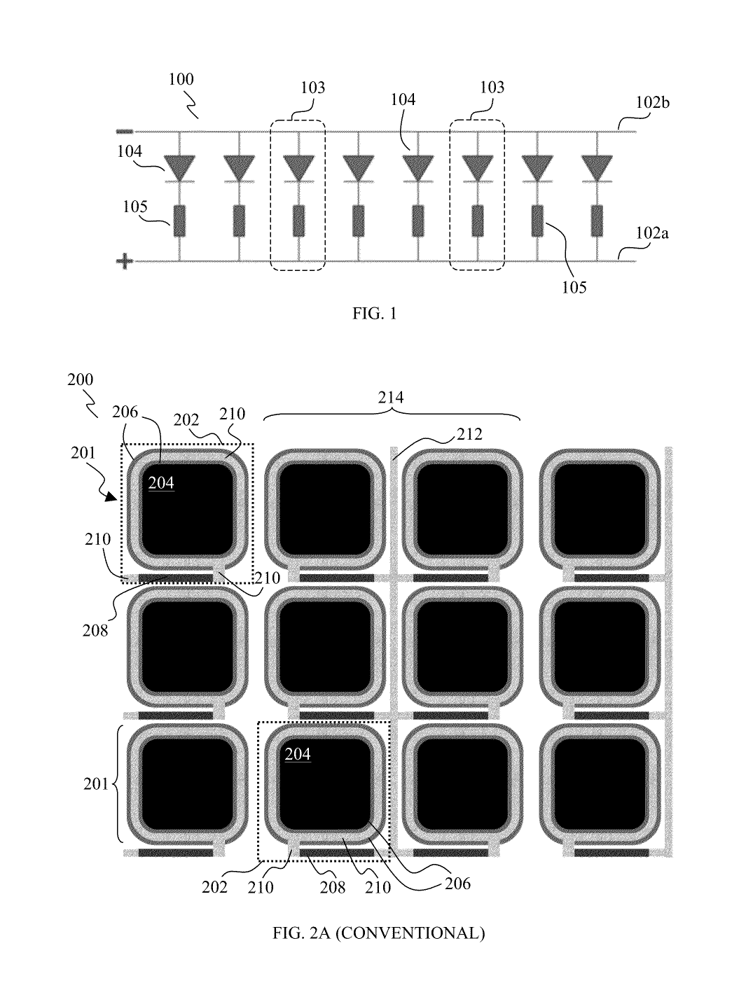

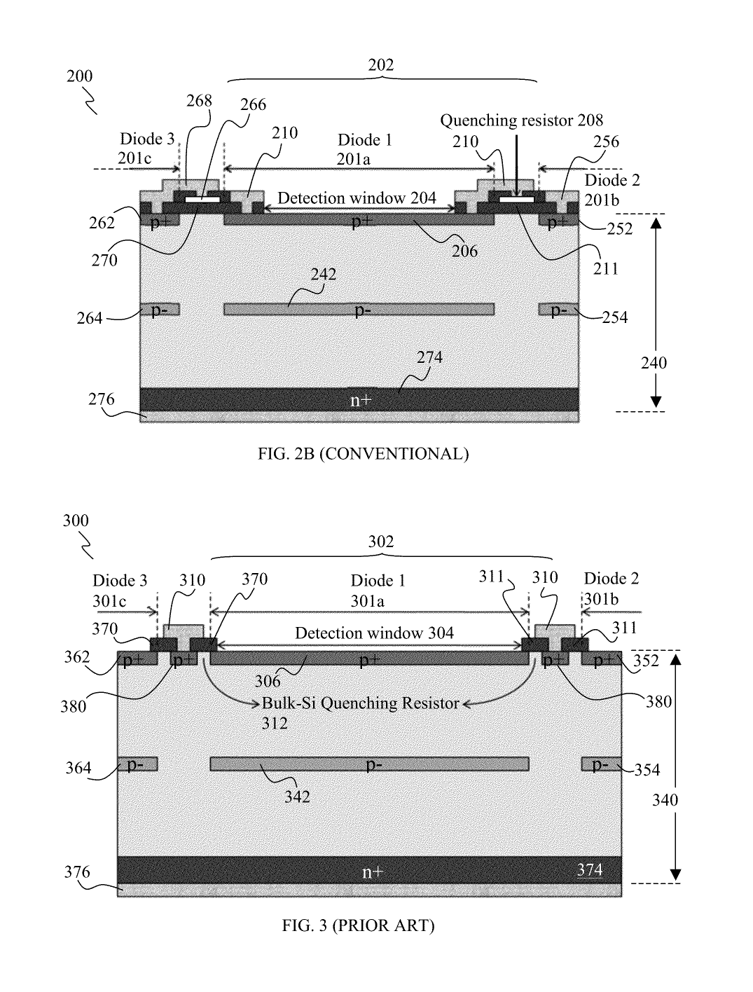

As a result of the inherent connection between the diode 630 and the resistor structure 600, metal wires used in conventional devices may be eliminated in the SiPM cells of various embodiments. As may be seen in FIGS. 6A and 6B, no metal wires may be found in the active region 628, and therefore the entire active region 628 of the SiPM cell 621a may be used for light detection. This is similarly applicable to the other cells, e.g. 621b, 621c, etc. of the VR-SiPM device 620. As no metal wires are present or necessary in the active regions, e.g. 628, the VR-SiPM devices 620, 650 may have larger detection windows as compared to the conventional SiPM devices 200, 300 (FIGS. 2A, 2B and 3). Therefore, the fill factor of the respective VR-SiPM cells. e.g. 621a, 621b, 621c, and the overall VR-SiPM devices 620, 650 may be increased, as compared to the SiPM devices 200, 300. Consequently, the VR-SiPM devices 620, 650 may also have a high detection efficiency.

Furthermore, no poly-Si resistors may be necessary in the VR-SiPM devices 620, 650 of various embodiments, which may accordingly simplify the fabrication process and reduce the fabrication costs, as no poly-Si related processes may be required. Hence, a simplified fabrication process and high yield may be achieved, due to omission of poly-Si related steps. As each of the VR-SiPM devices 620, 650 includes an inherent diode-resistor connection, the VR-SiPM devices 620, 650 may be free of separate resistors, for example external poly-Si resistors, as quenching resistors.

As a result of the omission of poly-Si resistors and elimination of metal wires in the VR-SiPM cells, the surface of the SiPM array may remain flat and unstructured. Hence, a high fill factor may be achieved, due to the absence of metal wires and poly-Si resistors on the device surface.

Further, the design of the vertical quenching resistor 600 may be very flexible. Its resistance may depend on the area of the hole or gap 610 in the current blocking layer (p+ region 608) and the distance between the two electrodes (n+ regions 604, 606), rather than the area of the active region 628. Even when the epitaxial thickness and the area of the active region 628 are fixed, the resistance may still be easily tuned by changing the dimension of the hole 610, and/or adding more holes 610 in one SiPM cell, e.g. 621a. Therefore, VR-SiPMs with different cell sizes and/or possibly different quenching resistors may be processed and achieved simultaneously on one wafer.

Simulation and analysis of the devices of various embodiments will now be described by way of the following non-limiting examples. Numerical simulations may be performed to verify the functionality of the vertical bulk-Si quenching resistor and the SiPM structure of various embodiments. A Technology Computer Aided Design (TCAD)-based software was used to simulate the fabrication processes and the device characteristics. The SACM structure was used to build the SiPMs under simulation. For simplicity, a circular symmetry may be used for the layouts of the devices, and therefore, a cylindrical coordinate system was used for the simulation.

The performance of the vertical bulk-Si quenching resistor of various embodiments will now be described. The vertical bulk-Si resistor in the simulation was assumed to be achieved on an n+ substrate. Two epitaxial Si layers, both of which were 500 nm thick, were grown on the substrate. Two ion implantation processes were used to define p+ and n+ regions. The radius of the active region may be about 10 μm, while the center hole may have a diameter of about 1 μm. As a result of the use of the cylindrical coordinate system, only half of the cross-section needs to be simulated.

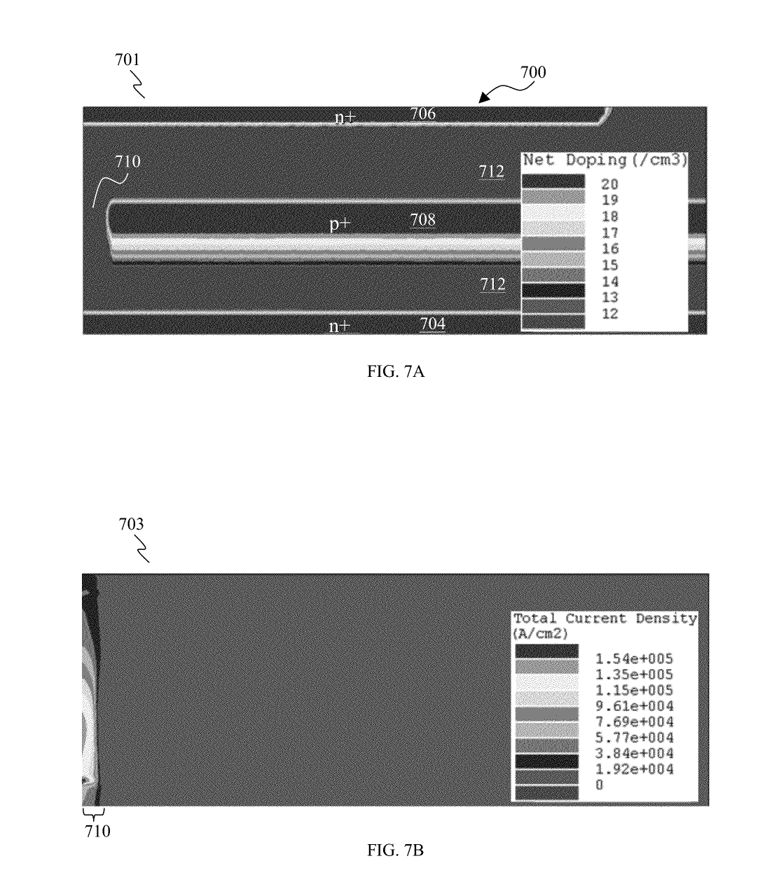

FIG. 7A shows a plot 701 of simulation results of the doping profile of a vertical bulk-Si resistor 700, according to various embodiments. The resistor 700 includes an n+ substrate 704, a p+ region 708 with a gap 710 defined therethrough, an n+ region 706, and intrinsic regions 712 defined by the Si epitaxial layers.

When a voltage is applied to the resistor 700, the n+ region 704-p+ region 708-n+ region 706 structure acts as two back-to-back diodes in series connection, which may block current flow, and therefore, the current may only find its way through the hole or gap 710. FIG. 7B shows a plot 703 of simulation results of the current density when an overvoltage (e.g. a 10 V bias) is applied to the substrate of the vertical bulk-Si resistor based on the embodiment of FIG. 7A. Plot 703, illustrating the simulated current density distribution in the resistor 700, shows the current flow through the gap 710.

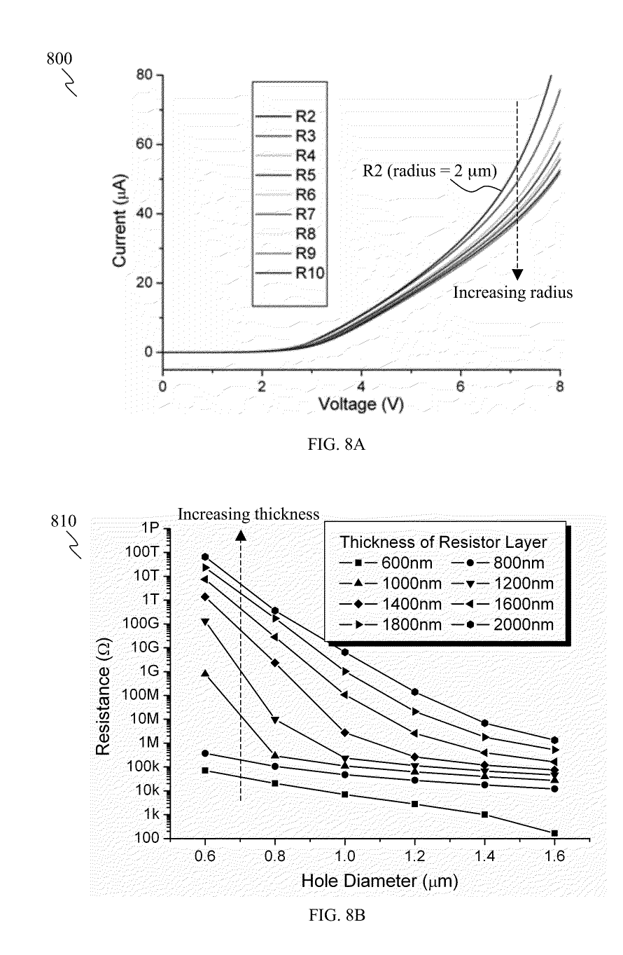

FIG. 8A shows a plot 800 of I-V (current-voltage) curves of vertical bulk-Si resistors for different radii of the active region, according to various embodiments. Plot 800 shows results where the radius of the active region varies from about 2 μm to about 10 μm. As may be observed in FIG. 8A, the current in the resistor increases with the voltage applied only when the voltage is higher than a threshold voltage of about 2.5 V. The resistance is in the order of about 10⁵Ω and is not strictly linear. This is because the width of the depletion region in the pn junction varies with the voltage applied, which may accordingly affect the effective cross-sectional dimension of the resistor. Furthermore, the resistance linearity improves as the dimension of the active region increases. When the radius of the active region goes above 8 μm, the I-V curve shows no obvious dependence on the area of active region.

The resistance variation of the vertical bulk-Si resistor with the total thickness of the resistor layer (e.g. based on FIG. 7A, the thickness may be defined by and between the n+ regions 704, 706), and the dimension of the hole was also determined. FIG. 8B shows a plot 810 of resistance variation for vertical bulk-Si resistors under a 5 V bias for different thicknesses of the resistor layer and diameters of the holes, according to various embodiments. The p+ region (e.g. 708, FIG. 7A) may be assumed to be always located in the middle of the resistor layer, and the resistor is biased under 5 V. As may be seen from the calculation results shown in FIG. 8B, the resistance may vary in a very large range using the resistor structure of various embodiments.

The performance of the VR-SiPM Cell of various embodiments will now be described. Based on the above simulation results for the resistor structure, the vertical bulk-Si quenching resistor of various embodiments may be incorporated into an SiPM cell. In the simulation process, the resistor structure was first defined by silicon epitaxial growth and ion implantation using the same process conditions as described above. The resistor hole (gap) may have a diameter of about 1 μm while the radius of the active region remains at approximately 10 μm. The total thickness of the resistor layer may be about 1 μm. After that, the API) structure was defined, also by Si growth and ion implantation. The diode layer may have a thickness of 1 μm. Thus, the total epitaxy thickness for the whole device layer may be approximately 2 μm.

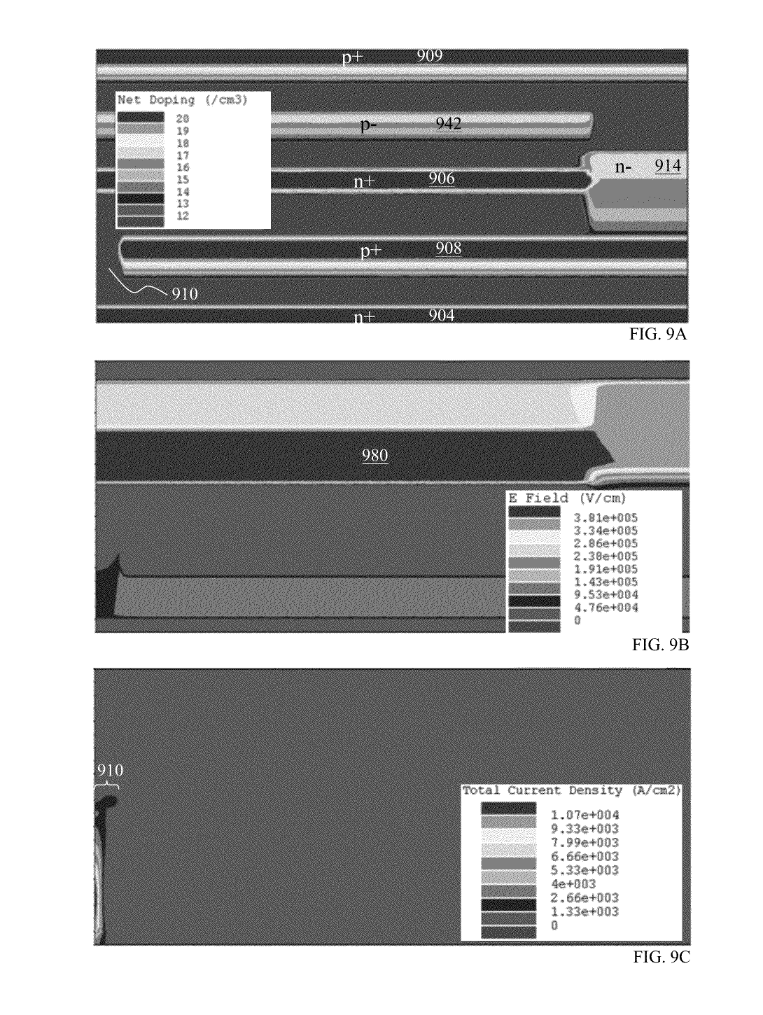

FIGS. 9A, 9B and 9C show plots of simulation results of the doping profile of a silicon photomultiplier (SiPM) device (VR-SiPM device), the electric field distribution and the current density distribution of the VR-SiPM device operating above the breakdown voltage, respectively, according to various embodiments.

FIG. 9A shows a plot of simulation results of the doping profile of the VR-SiPM device having n+ regions 904, 906 and a p+ region 908 with a defined gap 910, to define a resistor structure, and a p+ region 909 (which serves as an active region) and a p− region 942, which together with the n+ region 906 define a diode (e.g. APD diode). The VR-SiPM device further includes an n− region 914. As previously described, the n− region 914 may be introduced, not only as a guard ring for the diode, but also as a blocking area to prevent or at least minimise any direct current flow between the two p+ regions 908, 909.

When the whole VR-SiPM structure is reversely biased above the breakdown voltage, the electric field distribution within the VR-SiPM device may be as shown in FIG. 9B. The highest electric field may be located in the multiplication region 980 of the APD diode, as expected.

The current density, as illustrated in FIG. 9C, shows a similar distribution with that of a separate vertical bulk-Si resistor 700 shown in FIG. 7B. This means that the resistor structure may work well when it is incorporated with the APD to form a VR-SiPM cell.

In order to compare the performances of the VR-SiPM device and conventional SiPM devices, a structure similar to that shown in FIG. 2B was constructed and simulated as well. The device layer in the conventional SiPM device 200 has identical cross-sectional structures and doping profiles as those for the APD part (the upper part), having the n+ region 906, the p− region 942 and the p+ region 909, of the VR-SiPM device shown in FIG. 9A. For the conventional SiPM device 200, the total thickness of the device layer is about 1 μm and the radius of the active region is about 10 μm. The resistance of the serial poly-Si quenching resistor 208 of the conventional SiPM device 200 was set to be 10⁵Ω.

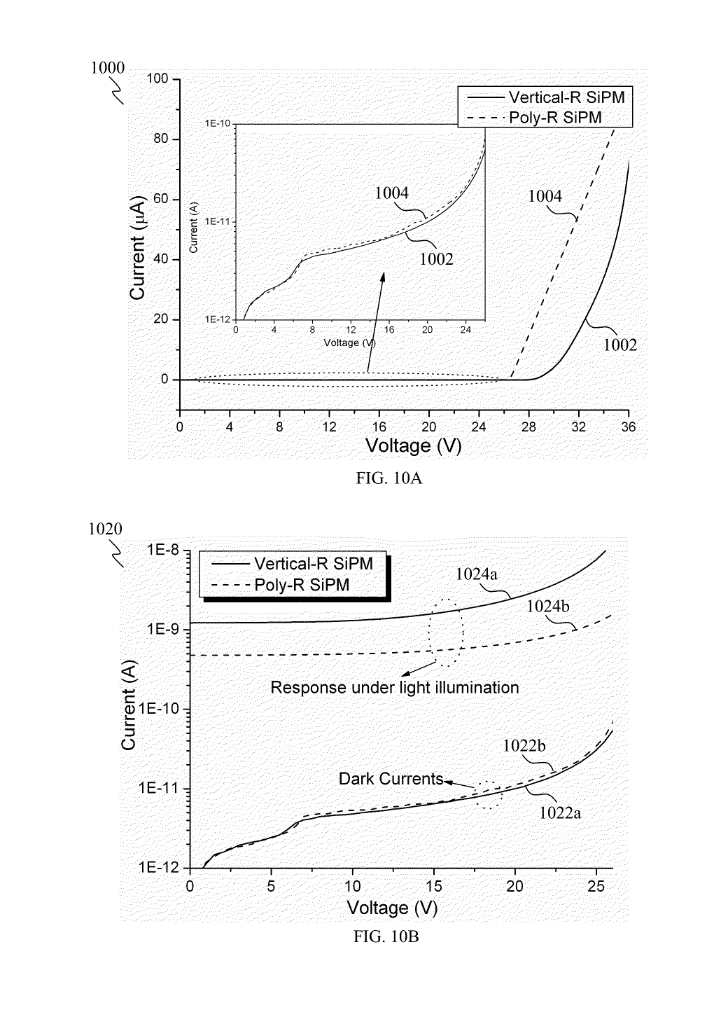

FIG. 10A shows a plot 1000 of I-V (current-voltage) curves of a silicon photomultiplier (SiPM) cell (VR-SiPM cell) of various embodiments and a conventional SiPM cell having identical structures, as described above. Plot 1000 shows result 1002 for the VR-SiPM device and result 1004 for the conventional SiPM cell having a poly-Si resistor.

As may be seen, the breakdown voltage of the VR-SiPM cell may be about 2-3 V higher than that of the conventional SiPM cell. This increase for the VR-SiPM cell is in accordance with the threshold voltage of the vertical resistor observed in FIG. 8A. When the applied voltage goes above the breakdown voltage, the slope of the I-V curve of the VR-SiPM cell is still comparable to that of the conventional SiPM cell with a 10⁵Ω poly-Si quenching resistor, although the resistance of the vertical resistor of the VR-SiPM cell may not be linear. Furthermore, as shown in the inset of FIG. 10A, the dark current of the VR-SiPM (result 1002) is almost identical to that of the conventional SiPM (result 1004), in spite of the thicker device layer adopted for the VR-SiPM cell. This is because the electric field in the resistor part is very low (see FIG. 9B), and the defects in this region may not contribute to the dark current.

The light responses of the VR-SiPM cell and the conventional SiPM cell may also be investigated by simulation. The respective devices may be illuminated by a collimated light beam with a wavelength of about 460 nm and a power density of approximately 1 mW/cm². The incident light was vertically launched to the device surface.

FIG. 10B shows a plot 1020 of simulation results for the blue light responses of the VR-SiPM cell of various embodiments and the conventional SiPM cell, illustrating the I-V curves under illumination, together with the corresponding dark current curves of the respective SiPMs. Plot 1020 shows results 1022a, 1024a for the dark current and the blue light (460 nm) response, respectively, for the VR-SiPM device, and results 1022b, 1024b for the dark current and the blue light (460 nm) response, respectively, for the conventional SiPM device. As may be seen, the dark current of the VR-SiPM device is almost the same to that of the conventional SiPM device. However, a larger response to blue light may be observed in the VR-SiPM device. This observation farther confirms the close connection between the detection sensitivity and the fill factor of the device.

Based on the area of the detection window, the till factor of the conventional SiPM device may be calculated to be about 37%. For its VR-SiPM counterpart, the “geometric fill factor” should be 100% since the surface of the SiPM array is flat and unstructured. However, as the responses of the devices may also depend on the location of the incident light beam, the “effective fill factor” of the VR-SiPM device ma be estimated according to its light response as shown in FIG. 10B. According to the simulation, when the VR-SiPM device is not biased, its current response is approximately 2.55 times that of the conventional SiPM device. Thus, the effective till factor of the VR-SiPM device may be estimated to be about 94.5% (=37%×2.55).

As described above, various embodiments may provide a semiconductor photomultiplier device (e.g. a silicon (Si) photomultiplier device) structure, where all poly-Si related processes may be omitted or eliminated in forming the structure. Instead, vertical bulk quenching resistors (e.g. vertical bulk-Si quenching resistors) may be introduced in the device. There may also be elimination of metal wires in the array area of the device. In forming the photomultiplier device of various embodiments, there may be ease of fabrication and/or flexibility of design. The photomultiplier device having the structure as described in the context of various embodiments may achieve a higher photon detection efficiency and/or a higher yield, without or with minimal sacrifices in terms of other performances/parameters of the device.

While the invention has been particularly shown and described with reference to specific embodiments, it should be understood by those skilled in the art that various changes in form and detail may be made therein without departing from the spirit and scope of the invention as defined by the appended claims. The scope of die invention is thus indicated by the appended claims and all changes which conic within the meaning and range of equivalency of the claims are therefore intended to be embraced.

1. A semiconductor resistor structure comprising:
a substrate;
a first region of a first conductivity type in the substrate;
a second region of the first conductivity type in the substrate, the first region and the second region arranged one over the other; and
an intermediate region of a second conductivity type in between the first region and the second region, wherein at least one gap is defined through the intermediate region and overlapping with the first region and the second region.

2. The semiconductor resistor structure as claimed in claim 1, wherein the at least one gap has a dimension between about 100 nm and about 100 μm.

3. The semiconductor resistor structure as claimed in claim 1, wherein a plurality of gaps are defined through the intermediate region, the plurality of gaps overlapping with the first region and the second region.

4. The semiconductor resistor structure as claimed in claim 1, wherein the intermediate region is spaced apart from at least one of the first region or the second region.

5. The semiconductor resistor structure as claimed in claim 1, wherein the intermediate region is arranged equidistant from each of the first region and the second region.

6. The semiconductor resistor structure as claimed in claim 1, wherein a distance between the first region and the second region between about 100 nm and about 100 μm.

7. The semiconductor resistor structure as claimed in claim 1, wherein the first region is thicker than the second region.

8. The semiconductor resistor structure as claimed in claim 1, wherein the first conductivity type is an n-type conductivity type, and wherein the second conductivity type is a p-type conductivity type.

9. The semiconductor resistor structure as claimed in claim 1, wherein the first conductivity type is a p-type conductivity type, and wherein the second conductivity type is an n-type conductivity type.

10. A semiconductor photomultiplier device comprising:
a substrate having a front side and a back side;
at least one cell comprising:
a first region of a first conductivity type adjacent to the back side;
a second region of the first conductivity type in the substrate over the first region;
an intermediate region of a second conductivity type in between the first region and the second region, wherein at least ore gap is defined through the intermediate region and overlapping with the first region and the second region; and
an active region of the second conductivity type adjacent to the front side.

11. The semiconductor photomultiplier device as claimed in claim 10, wherein a plurality of gaps are defined through the intermediate region, the plurality of gaps overlapping with the first region and the second region.

12. The semiconductor photomultiplier device as claimed in claim 10, wherein the intermediate region is spaced apart from at least one of the first region or the second region.

13. The semiconductor photomultiplier device as claimed in claim 10, wherein the intermediate region is arranged equidistant from each of the first region and the second region.

14. The semiconductor photomultiplier device as claimed in claim 10, wherein the at least one cell further comprises another intermediate region of the second conductivity type between the active region and the second region.

15. The semiconductor photomultiplier device as claimed in claim 14, wherein the other intermediate region is spaced apart from at least one of the active region or the second region.

16. The semiconductor photomultiplier device as claimed in claim 10, wherein the at least one cell further comprises another intermediate region of the first conductivity type between the active region and the second region.

17. The semiconductor photomultiplier device as claimed in claim 16, wherein the other intermediate region at least substantially contacts the active region.

18. The semiconductor photomultiplier device as claimed in claim 10, comprising:
a plurality of cells comprising the first region and the active region,
wherein each cell of the plurality of cells comprises:
a second region of the first conductivity type in the substrate over the first region; and
an intermediate region of the second conductivity type in between the first region and the second region, wherein at least one gap is defined through the intermediate region, the at least one gap overlapping with the first region and the second region.

19. The semiconductor photomultiplier device as claimed in claim 18, wherein each cell further comprises another intermediate region of the first conductivity type or the second conductivity type between the active region and the second region.

20. The semiconductor photomultiplier device as claimed in claim 18, further comprising:
at least one guard region of the first conductivity type,
wherein a guard region of the at least one guard region is arranged in between respective second regions of adjacent cells of the plurality of cells.
